(19) United States
(12) Patent Application Publication
(10) Pub. No.: US 2015/0233973 A1
(43) Pub. Date: Aug. 20, 2015

(54) Method of Manufacturing a Test Socket Body of an Impedance-Matched Test Socket

(71) Applicants: Tim WOODEN, Santa Clara, CA (US); Sergey IVANKOV, Santa Clara, CA (US)

(72) Inventors: Tim WOODEN, Santa Clara, CA (US); Sergey IVANKOV, Santa Clara, CA (US)

(21) Appl. No.: 14/199,011

(22) Filed: Mar. 6, 2014

Related U.S. Application Data
(63) Continuation of application No. 14/181,943, filed on Feb. 17, 2014.

(51) Int. Cl. G01R 3/00; G01R 1/04

(52) U.S. Cl. CPC G01R 3/00; G01R 1/0441

(57) ABSTRACT

Proposed is a method for manufacturing a coaxial impedance-matched test socket having a socket body with a structure similar to a system of redistributed coaxial cable inserts, where the core of each insert comprises a pogo pin, a metal layer that surrounds the pogo pin functions as a shielding element of the core, and an air gap and an insulation filling between the pogo pin and the shielding metal part function as an isolator. A unique feature of the method consists of employing standard and commercially available parts the use of which significantly decreases the number of manufacturing steps and simplifies the manufacturing process. In addition, the process involves operations that provide simultaneous multiposition treatment which accelerates production.

### FIELD OF THE INVENTION

The present invention relates to the field of testing electrical contacts in electrical and electronic devices, in particular to a method of manufacturing of the test socket body of an impedance-matched test socket used, e.g., in operations of final high speed testing (FHST). More specifically, the invention provides a method for manufacturing the test socket body of an FHST socket that eliminates crosstalk, creates impedance-controlled signals of different values on the same socket, and at the same time makes it possible to manufacture the mentioned sockets less expensively than by traditional CNC (computer numerical control) machining by using printed circuit board technology.

### BACKGROUND OF THE INVENTION

In general, when a process of manufacturing a semiconductor chip such as an integrated circuit (IC) or the like is ended, an electric performance, quality, etc., of the semiconductor chip are tested. In general, when the process of manufacturing a semiconductor chip, such as an IC, or the like, is completed, electrical performance, quality, etc., of the semiconductor chip are tested. When a semiconductor device is to be tested, a test socket is placed between the lead contacts of the IC and the terminals of the measurement device.

Current flows from the test terminals of the test device into the lead terminals of the semiconductor chip through the test socket, and signals respectively output from the lead terminals are analyzed to determine whether the semiconductor chip is abnormal.

The increased working frequency of IC devices creates a challenge to FHST testing because traditional test sockets made out of insulative material, such as plastics and ceramics, do not perform well. FHST test sockets made of insulative materials with high or low dielectric permittivity cannot prevent contactor crosstalk because the wavelength becomes comparable to the length of the contactors whereby the contactors behave as antennas and propagate radio frequency.

There are many types of test sockets, some of which are aimed at eliminating crosstalk and matching impedance.

However, manufacturing of testers of the aforementioned type is rather complicated since the manufacturing process involves high precision operations and the use of expensive equipment of high accuracy.

US Patent Application Publication No. 20130285692 published on Oct. 31, 2013 (inventor: J. Lee) discloses a test socket including electrode supporting portion and a method of manufacturing of the aforementioned test socket. The method consists of several steps. The first step is forming an elastic conductive sheet including a conductive portion, in which a plurality of conductive particles are arranged in an insulating material so that conductivity is exhibited in a thickness direction, at each position of a subject device corresponding to a terminal, and an insulating supporting portion that supports and insulates the conductive portion at a same time. The second step is forming a sheet type connector formed of a sheet member to which an electrode portion is coupled at each corresponding position to the conductive portion. The sheet type connector is attached to the elastic conductive sheet. Following this, a cut is made by cutting at least a portion of the sheet member between adjacent electrode portions. The sheet type connector is coated with insulating material on the sheet type connector. An electrode supporting portion is then formed by removing the insulating material disposed on a portion corresponding to a center portion of the electrode so that the center portion of the electrode is exposed. The method further comprises the step of removing insulating material disposed on a portion of the electrode supporting area corresponding to the cut portion.

US Patent Application Publication No. 20110102009 published on May 5, 2011 (Inventor: J. lee) discloses a test socket electrical connector, and method for manufacturing of the test socket. The method consists of: fabricating contact pins having sharp first ends; plating an adhesive material on second ends of the contact pins; and electrically connecting springs to the contact pins by adhering the springs, which are aligned by a housing having through-holes formed therein to correspond in position to terminals of a semiconductor device, to the adhesive material. The step of fabricating of the contact pins comprises: forming grooves having wedge shapes in a substrate by using etching; depositing an oxide film on the substrate and patterning a photoresist (PR). The etched grooves are then; plated with a conductive material, such as nickel-cobalt (Ni—Co) or nickel-tungsten (Ni—W). The adhering operation comprises heating the adhesive material to melt the adhesive material; inserting ends of the springs into the melted adhesive material; and cooling the adhesive material.

U.S. Pat. No. 8,535,101 granted on Sep. 17, 2013 to K. Suzuki, et al. discloses a test socket that comprises an upper housing that is made from a dielectric material and contains a plurality of holes for pogo pins. Inserted into these holes are insulating pilot inserts for aligning the pogo pins with respect to the bumps which are inserted into the guide plate of the test socket located above the upper housing. The lower housing, which is also made from the dielectric material, contains guide holes for the lower ends of the pogo pins. The structure is provided with metal sleeves, which, in turn, are inserted into the isolation tubes which are inserted into the holes of the upper housing. In this structure, matching of impedance is carried out by selecting the length of the isolation tubes.

The manufacturing and assembling of such a test socket is expensive and complicated since the process involves manufacturing of a plurality of small different parts which have to inserted one by one into the respective holes of the upper housing. This structure does not provide complete screening of the pogo pins and there cannot completely prevent cross talking.

### BRIEF DESCRIPTION OF THE DRAWINGS

FIG. 1 is an exploded perspective view of the test socket of the present invention.

FIG. 2 is a part of a sectional view through the test socket of the present invention in an assembled state.

FIG. 3A to 3F are sectional views illustrating by sequential operations used in the manufacture of the coaxial impedance-matched test socket of the type shown in FIG. 2.

FIG. 4 is a sectional view of a finished probe retainer, only one of the probe retainers being shown as the manufacturing process thereof is substantially the same.

### SUMMARY OF THE INVENTION

The invention relates to a method for manufacturing a probe retainer used in a coaxial impedance-matched test socket for testing electrical/electronic devices, e.g., integrated circuits. The socket comprises a probe holder that holds a plurality of pogo pins positioned in accordance with the arrangement of contact leads of a specific Integrated circuit. The probes are held in place between an upper probe retainer and a lower probe retainer. An integrated circuit is to be tested is held in a guide plate which is provided with guide holes for the ends of the contact leads of the test circuit in order to maintain them in contact with the upper tips of the pogo pins, while the lower probe retainer is supported by a test board. The latter is connected to a tester and comprises a number of contact pads, connected to respective measurement instruments or in some cases system boards for measuring the electric signals obtained during testing of the integrated circuit.

A unique feature of the method of the invention consists of using standard parts the use of which significantly decreases the number of manufacturing steps and simplifies the manufacturing process. In addition, the process involves operations that provide simultaneous multiposition treatment which accelerates production.

More specifically, the method of manufacturing a test socket body used in a specific test socket for testing an object with a plurality of contact leads as described in pending parent U.S. patent application Ser. No. 14/181,943 filed on Feb. 17, 2014. comprises the steps of:
providing a first laminate that comprises a dielectric sheet coated with a metal layer at least on one side;
forming in the metal-coated laminate a plurality of first through holes having inner surfaces and located in positions that correspond to positions of the contact leads of the test object;
coating at least the inner surfaces of each first through hole with a metal layer thus obtaining first metal-coated through holes;
filling the first metal-coated through holes with a dielectric material thus forming dielectric fillings;
forming second through holes in the dielectric fillings leaving at least partially the dielectric material between the metal layer and the second through holes, thus producing a finished first probe retainer;
providing a second finished probe retainer which is similar to the first finished probe retainer and which is produced by repeating the manufacturing steps of the first finished probe retainer;
providing a metallic probe holder comprising a metal plate having a plurality of third through holes the positions of which correspond to positions of the through holes in the first finished probe retainer and the second finished probe retainer;
providing a conductive substrate having a plurality of contact pads the number of which corresponds to the number of the contact leads of the test object and that are intended for connection to devices for measuring parameters of the test object;
providing a plurality of pogo pins that can be inserted into the second through holes of the first and second finished probe retainers;
providing a pogo pin securing openings in the dielectric material of the first and second probe retainer left after forming the second through holes, the positions of the pogo pin securing openings corresponding to the positions of the contact leads of the test object and said pogo pin securing openings being formed simultaneously with the step of forming second through holes in the dielectric fillings, the pogo pins being of a first type pogo pins and a second type pogo pins, wherein the pogo pins of the first type have an electrical contact with the third through holes via a press fit or sliding fit with the third through holes when inserted therein and the pogo pins of the second type do not have a physical and electrical contact with the third through holes when inserted therein; and
assembling the probe holder by inserting the pogo pins of the first type into the third through holes of the probe holder to contact with the support surface thus protruding the ends of the pogo pins of the first type from the probe holder, inserting the protruding ends of the pogo pins of the first type into securing openings of the second probe retainer, inserting the pogo pins of the second type into the third through openings of the probe holder and further to the pogo pin securing openings of the lower probe retainer, and fitting the pogo pin securing openings of the upper probe retainer on the ends of the pogo pins of the first and second type on the side opposite to the lower probe retainer thus completing assembling of the test socket body.

### DETAILED DESCRIPTION OF THE INVENTION

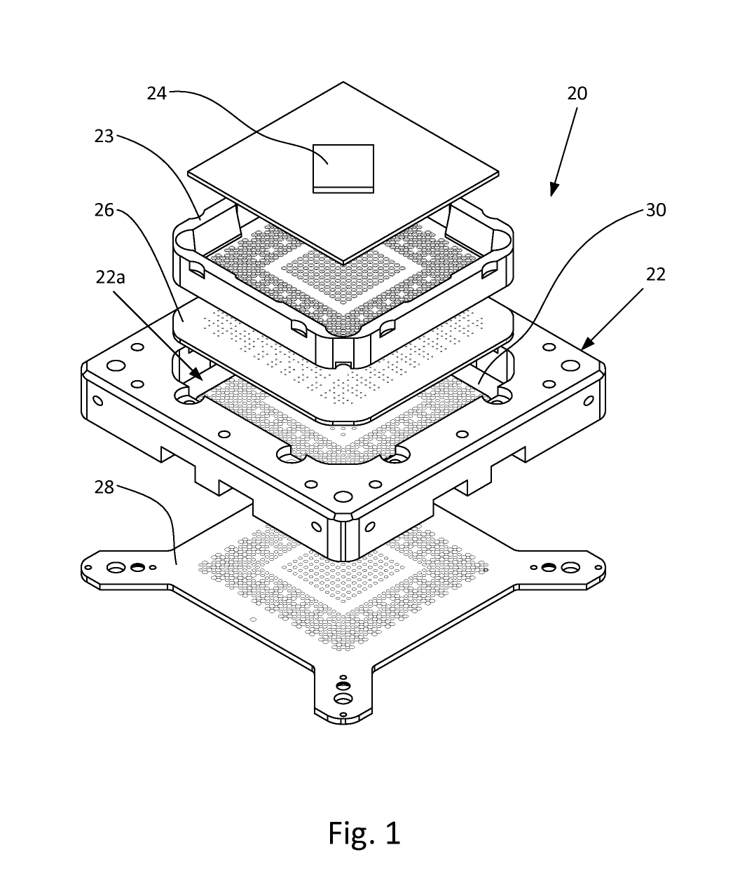

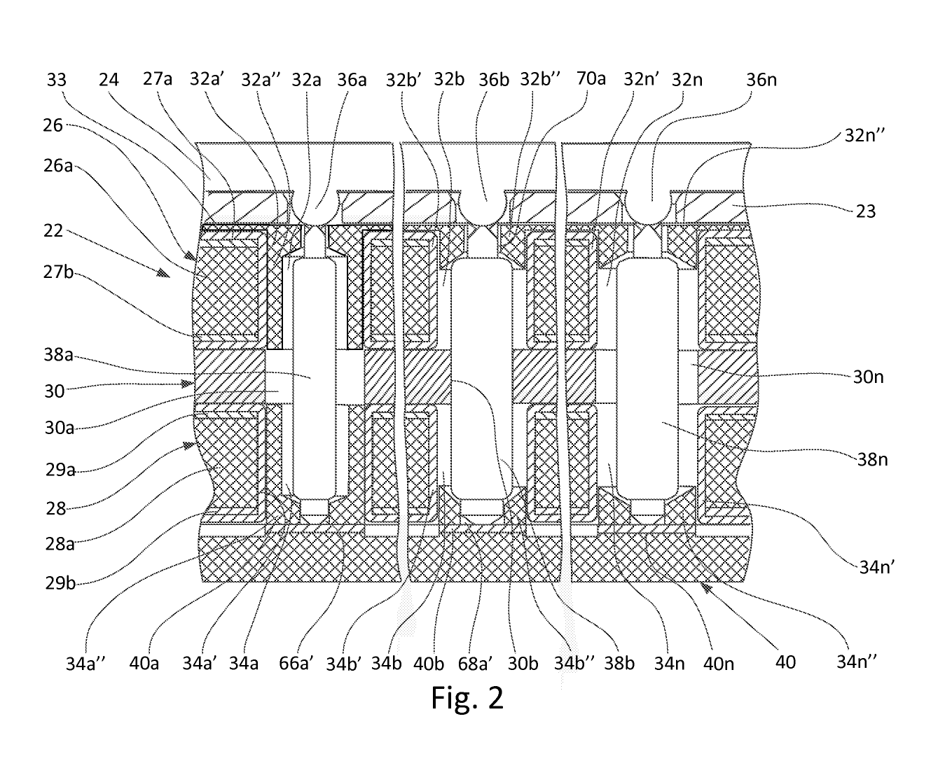

Since the method of the invention relates to manufacturing of a test socket body of an impedance-matched test socket having a specific structure shown in FIGS. 1 and 2, it will be advantageous first to consider the structure of the test socket body itself.

A test socket for the manufacture of which the method of the invention is intended is shown in FIG. 1, which is an exploded perspective view of the test socket. It can be seen that the test socket, which in general is designated by reference numeral 20, comprises a test socket body 22, which, is described below with reference to FIG. 2, and comprises a metallic probe holder 30 sandwiched between two laminated probe retainers, i.e., the upper probe retainer 26 and a lower probe retainer 28. FIG. 2 is part of a sectional view through the test socket of the present invention in an assembled state.

The test socket body 22 has a recess 22a inserted into the upper probe retainer 26 and the lower probe retainer 28. The upper probe retainer 26 comprises a double-sided laminated plate made from a dielectric material 26a coated on both sides with thin metal layers 27a and 27b and provided with through holes, only three of which are shown, i.e., holes 32a, 32b, and 32n. Similarly, the lower probe retainer 28 comprises a double-sided laminated plate made from a dielectric material core 28a coated on both sides with thin metal layers 29a and 29b and provided with through holes, only three of which are shown, i.e., 34a, 34b, and 34n.

The probe holder 30 is made from a conductive material, e.g., copper, aluminum, brass, etc. The probe holder 30 also has arrays of holes, only three of which, i.e., holes 30a, 302b, and 30n, are shown. The holes 30a, 302b, and 30n are aligned with the holes 32a, 32b, . . . 32n and 34a, 34b, . . . 34n of the upper and lower probe retainers 26a and 28a, respectively, and have the same diameters, except for the holes 30b, which are intended for insertion of the grounding pogo pins that must have electrical contact with the metal probe holder 30 of the grounding system.

Number and density distribution of all aligned holes depends on the arrangement of lead contacts of a specific Integrated circuit of the test object 24 that is to be tested.

As mentioned above, both top and lower probe retainers 26 and 28, respectively, are double-sided laminated plates made from a dielectric material coated with thin metal layers.

A guide member 23 is provided between the test object 24 and the upper probe retainer 26 for aligning the lead contacts (not shown in FIG. 1) with the tips of the pogo pins, which are shown and described in connection with FIG. 2 below.

The inner surfaces of the holes 32a, 32b, and 32n of the upper probe retainer 26 are coated with metal layers 32a′, 32b′, 32n′, which may be applied, e.g., by electroplating. In the coating operation, the inner surfaces of the holes are covered with thin metal layers as well as the entire surface of the probe retainers, i.e., the flat metal-coated surfaces of the probe retainers 26 and 28.

The interiors of the metal-coated holes, in turn, are coated with hollow isolation inserts 32a″, 32b″, and 32n″. These inserts are formed by filling the aforementioned holes with a dielectric material such as PTFA (polytetrafluoroethylene), polyester, polyether, fluorocarbon, or the like, with subsequent formation of the holes for insertion of the pogo pins. The holes have dielectric inserts for two reasons: (1) if a hole ID has to be small due to small pitch, the use of the dielectric insert prevents pogo-pin contact with the metal layer inside the hole; and (2) use of a dielectric insert makes it possible to match impedance by selection of dielectric type, layer thickness, etc. In other words, the predetermined thickness and/or predetermined composition of the dielectric material of the isolation inserts can be used to obtain desired impedance limiting characteristics.

The inner surfaces of the holes 34a, 34b, and 34n of the lower retainer 28 are coated with metal layers 34a′, 34b′, 34n′, which may be applied, e.g., by electroplating. The interiors of the metal-coated holes, in turn, are coated with hollow isolation inserts 34a″, 34b″, and 34n″. These inserts are formed by filling the aforementioned holes with a dielectric material such as PTFE (polytetrafluoroethylene), polyester, fluorocarbon, or the like, with subsequent formation of the holes for insertion of the pogo pins. Reference numeral 33 designates a continuous thin insulation layer which is formed from the dielectric material of the isolation inserts 32a″, 32b″, . . . 32n″ on the surface of the thin metal layers 27a simultaneously with the formation of the aforementioned inserts when the insulation material of the isolation inserts fills the holes 32a, 32b, . . . 32n. In other words, this thin insulation layer is continuous except for holes provided to ensure contact of the pogo pins with the respective lead contacts of the object being tested and may comprise a part of the isolation inserts formed in the holes of the upper and lower probe retainers 26 and 28, respectively. Existence of such an insulation layer 33 provides an additional isolation of the solder bumps 36a, 36b, . . . 36n from accidental contact with metallic parts of the test socket body 22.

As seen in FIG. 2, contacts between lead terminals, hereinafter referred to as bumps, 36a, 36b, . . . 36n of the test object, i.e., the integrated-circuit chip 24 (FIG. 1), and a test board 40, which is connected to a measurement system (not shown), is carried out through spring probes 38a, 38b, . . . 38n. Such spring probes, which are also known and referred to as pogo pins, are standard devices available in various types and dimensions, and therefore their structure is beyond the scope of the present invention. For example, see, e.g., U.S. Pat. No. 8,062,078 granted to Asai, et. al, on Nov. 22, 2011.

Although only three pogo pins are shown in FIG. 2, there is a plurality of pogo pins of the depicted types. All of the selected pogo pins have point contacts at both ends, although this is not a compulsory condition.

The pogo pin 38n is a power pogo pin, which is intended for applying electrical power from respective contact pads, such as a contact pad 40n of the test board 40 to the respective bump 36n of the integrated circuit 24 (FIG. 1) to be tested.

The pogo pin 38b is a grounding pogo pin, which grounds the bump, such as the bump 36b (FIG. 2) of the integrated circuit 24 through the electrical contact with the metallic probe holder 30. The pogo pin 38b connects the respective bump 36b with a corresponding contact pad 40b of the test board 40.

The pogo pin 36a is a control pogo pin, which transmits a working signal (control signal) from the integrated circuit 24 to the test board 40 through its contact with the bump 36a and the respective contact pad 40a of the test board 40.

It is understood that the number of pogo pins corresponds to the number of the respective terminals, or bumps, on the integrated circuit 24.

It can be seen that the holes 30a, 30b, . . . 30n of the probe holder 30 have different diameters in order to accommodate pogo pins of different types, since, depending on their functions, these pins have different diameters. Thus, the hole 30b is smaller in diameter than the holes 30a and 30n, since the hole 30b provides an electrical contact of the grounding pogo pin 38b with the probe holder 30, which is grounded (see FIG. 2), while the power pogo pin 38n and the control pogo pin 38a are inserted into the holes 30n and 30a, the side walls of which are spaced from the side walls of the respective pogo pins.

It is understood that the contact pads 40a, 40b, . . . 40n are connected to respective measurement instruments (not shown) for measuring the electrical signals obtained during testing of the integrated circuit 24.

Thus, the uniqueness of the coaxial impedance-matched test socket 20 of the invention consists of power pogo pins, control pogo pins, and grounding pogo pins that are shielded from the environment by metal parts, except that the grounding pins have electrical contact with the shielding metal parts, wherein isolation of the pogo pins from the metal parts is provided either through an air gap along, such as air gap 32a, 34a, etc., or through an air gap in combination with dielectric material, such as isolation insert 32a″, 34a″, etc.

Here we have a coaxial impedance-matched test socket having a socket body with a structure similar to a system of redistributed coaxial cable inserts wherein the core of each insert comprises a pogo pin, a metal layer, such as the metal layers 32a′, 34a′, etc., and the metal pin holder 30 comprise shielding elements of the core, and the isolation inserts 32a″, 34a″, etc., and air gaps between the pogo pins and the metal parts comprise insulators. For higher system efficiency in matching impedances between input (pogo pins) and output (test object 24), the isolation inserts 32a″ and 34a″, which are placed between the outer surfaces of the control pogo pins and the inner surface of the metal layers, are made from a dielectric material of high dielectric permeability. This feature is especially essential for those pogo pins that transmit high-frequency signals, e.g., several GHz, or higher. By selecting specific dielectric materials with the required dielectric parameters, full matching can be provided.

The applicants have found that construction of the test socket 20 provided with the above-described probe holder 30 and the system of redistributed and shielded pogo pins provides accurate testing with very high repeatability of measurement results.

By using formula (1), it is possible to define the probe diameter dᵢ of the control pogo pins 38a (FIG. 2), the diameter dₒ of the shielded holes 34a and 34b, and the type of insulator.

$${Z}_{0} = \frac{1}{2 π} \sqrt{\frac{{μ}_{0} {μ}_{r}}{{ɛ}_{0} {ɛ}_{r}}} ln ( \frac{d o}{d i} ) Ohms \qquad ( 1 )$$

where μᵣ is relative permeability, ∈ᵣ is relative dielectric constant, and Z₀=Θ is impedance of the probe. In order to satisfy the device under test ball pitch (<0.8 mm) and match, the impedance dielectric constant of insulator (∈ᵣ) should be minimal, or equal 1. Thus, the ideal insulator is an air gap 32a′, 34a″ (FIG. 2).

Having described the structure of the test socket, let us now consider in more details a method of the invention for manufacturing the above-described test socket. The proposed method significantly simplifies and reduces the manufacturing of this device and accelerates the production process.

A unique feature of the method of the invention consists of using standard parts the use of which significantly decreases the number of manufacturing steps and simplifies the manufacturing process. In addition, the process involves operations that provide simultaneous multiposition treatment which accelerates production.

More specifically, the method of the invention relates to manufacturing the test socket body 22 of the specific test socket 20 (FIG. 1) for testing an object having a plurality of contact leads as described in pending parent U.S. patent application Ser. No. 14/181,943 filed on Feb. 17, 2014.

The method is carried out by using two standard and commercially available one-sided or double-sided metal-coated probe retainers. Examples of such standard one-sided or double-side copper-coated sheets are products of DuPont Company known under trademark Pyralux®. The products are available in sheet form with either Pyralux® FR or LF acrylic adhesive. Also available, under the Nikaflex® brand name, is an epoxy adhesive based 3-layer clad in roll form.

All polyimide clads, also known as 2-layer, are available either as double-sided using a lamination based manufacturing process or single sided utilizing cast technology.

All copper-clad laminates are available with rolled, annealed copper or electro-deposited copper. In addition, both types are available with double-treated copper (nodules of electro-deposited copper on both sides of the copper foil). Double-treated copper, if used, eliminates surface preparation steps prior to resist or coverlay lamination.

Pyralux® laminated composites are typically used to produce high reliability, high density circuitry of flexible, rigid-flex, and all-flexible multilayer constructions. Especially suitable for high-speed high-frequency applications is fluoropolymer adhesive solutions for superior performance in high-speed and high frequency applications. DuPont™ Pyralux® TK combines DuPont™ Teflon® fluoropolymer and DuPont™ Kapton® polyimide film to create thin laminate and bondply constructions.

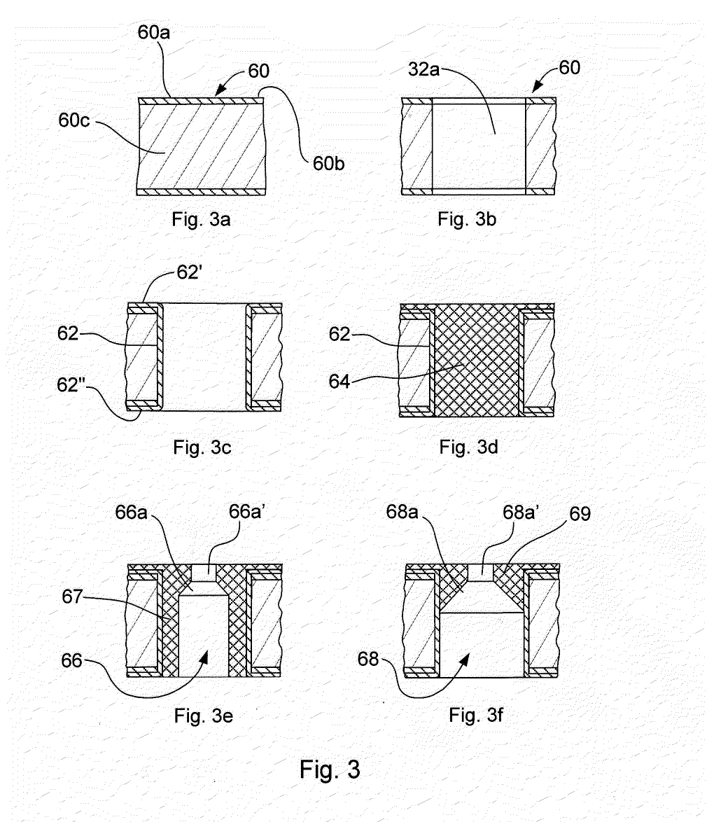

The obtained standard double-sided metal-coated sheet 60, a fraction of which is shown in FIG. 3A, is cut to dimensions suitable to fit into the recess 22a of the test socket body 22 (FIG. 1). The sheet has a core 60a made from a dielectric material, e.g., polyimide, and metal coatings 60b and 60c, e.g., of copper, on both sides of the core 60a.

Next, a plurality of holes such as holes 32a, 32b, . . . 32n (FIG. 2) are formed, e.g., by drilling on an NC drilling machine. Since the subsequent treatment of all the holes 32a, 32b, . . . 32n is identical, FIGS. 3A through 3F illustrate sequential operations only on one of the holes, e.g., the hole 32 (FIG. 3B). The holes 32a, 32b, . . . 32n have diameters and dimensions identical in both double-sided metal-coated probe retainers 26 and 28 (FIG. 2). Positions of these holes correspond to positions of the contact leads 36a, 36b, . . . 36n of the object 24 being tested.

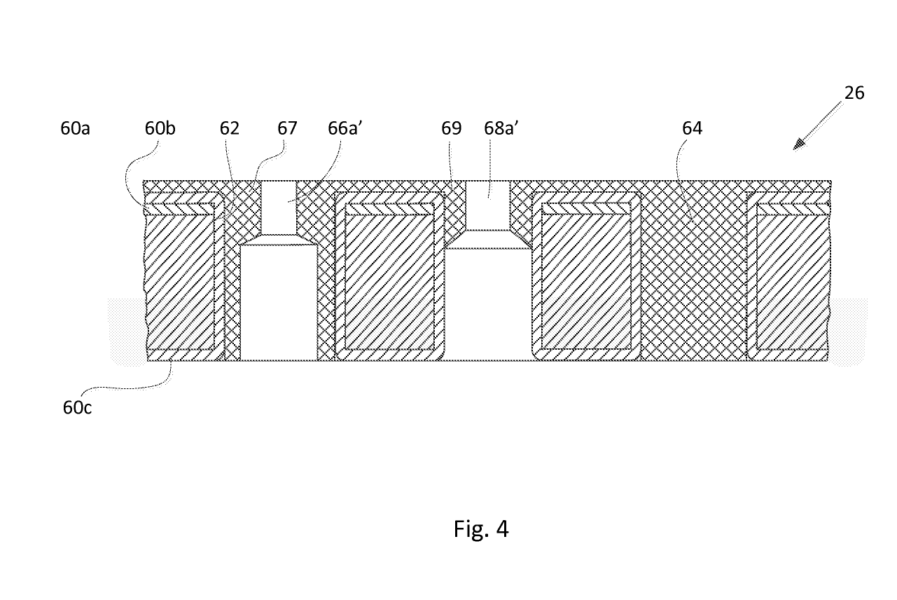

As shown in FIG. 4, the used standard metal-coated sheet is not necessarily a double coated and may comprise a dielectric-material laminate coated with a metal layer on one side only (see metal layer 60b in FIG. 4).

At least the inner surfaces of each through holes, such as the hole 32a shown in FIG. 3B, is coated with a metal layer 62. This is shown in FIG. 3C. The coating 62 may be made, e.g., of copper, and can be applied by different methods such as electroless deposition, precipitation in vacuum, electroplating, or the like. Since the metal coating method may involve placement of the probe retainer into a closed chamber, the coating metal 62 may cover not only the inner walls of the hole 32 but also the flat faces of the probe retainer, i.e., the metal-coating layers 60b and 60c of the standard sheet 60. This is shown by reference numerals 60′ and 60″ in FIG. 3C.

The next step of the method is filling of the metal-coated holes with a dielectric material for forming dielectric fillings such as filling 64 shown in FIG. 3D. As can be seen from FIG. 3D, the filling 64 is shielded from the outside by a metal layer 62.

Holes are then drilled through the dielectric fillings 64 in those of them which correspond to the positions of bumps 36a, 36b, . . . 36n of the object 34 (FIG. 2). As shown in FIGS. 3E and 3F, depending on the types of the pogo pins for which the aforementioned holes are designated, they may be of two types, i.e., the holes 66 and the hole 68. The holes 66 are formed by leaving a layer 67 over the entire length of the hole 66, while holes 68 are formed by leaving the dielectric material layer 69 only in a part of the hole, i.e., on the side of the pogo pin tip when the letter is inserted into its working position shown in FIG. 2.

On the side of the pogo pin tip each hole has a tapered shape designated by reference numeral 66a for the hole 66 and 68a for the hole 68, respectively. The final opening of each hole is formed as a cylindrical pilot opening 66a′ and 68a′, respectively for insertion of the tip of the respective pogo pin (FIG. 2) and thus for guiding and stabilizing the latter. If the holes 66 and 68 are drilled, then the tapered areas 66a and 68a are formed by countersinking, and the pilot openings 66a′ and 68a′ are drilled or pierced.

FIG. 4 is a sectional view of a part of a finished probe retainer, e.g., of the upper probe retainer 26a. Only one of the finished probe retainers is shown as the manufacturing process is substantially the same for both.

The lower probe retainer 28 (FIG. 2) may be manufacture simultaneously with the upper one as an identical copy thereof or the only difference may be that the lower probe retainer may not have the dielectric filling material 62′ (FIG. 3C) on the flat end face of the metal-coated standard plate 60 but be limited by coating only the inner walls of the of the metal coated holes.

The next step of the manufacturing process is providing a metallic probe holder 30 comprising a metal plate having a plurality of through holes, such as the holes 30b,30a, 30b, . . . 30n, the positions of which correspond to positions of the through holes i32a, 32b, . . . 32n (FIG. 2) in the first upper finished probe retainer 26 and the lower finished probe retainer 28. Some of the holes, such as a hole 30b shown in FIG. 2, has a diameter smaller than the other holes in order to provide physical and electrical contact of the walls of the holes in the metallic probe holder 30 with the outer surface of the grounding pin 38b (FIG. 2). Other holes, such as holes 30a and 30n are large enough to leave a space between the inner walls of the holes and the outer surfaces of the respective pogo pins 38a and 38n.

Following this, a conductive substrate 40 having a plurality of contact pads 40a, 40b, . . . 40n is provided. The number and positions of the contact pads correspond to the number and positions of the contact leads or bumps 36a, 36b, . . . 36n. The contact pads are intended for connection to devices for measuring parameters of the test object.

For assembling of the test socket body 22 of the invention (FIGS. 1 and 2), the finished lower probe retainer 28 is placed into the recess 22a (FIG. 1), the bottom of which retains a preliminary placed conductive supports 40 with the contact pads 40a, 40b, . . . 40n. The pogo pins 38a, 38b, . . . 38n are inserted into the pogo pin pilot openings, such as an opening 68a′ (FIG. 3F) of the isolation inserts 34b′ of the lower probe retainer 28. The opening 68a′ for the grounding pogo pins 38b should have a press fit or sliding fit with the grounding pogo pins. The lower tips of the pogo pins come into contact with the contact pads 40a, 40b, . . . 40n.

Being inserted into the openings 68a′, the upper ends of the pogo pins 38b protrude upward. Then the upper probe retainer 26 is placed from the top onto the metal probe holder 30 so that its pilot openings, such as the opening 70a, are fit onto the upper tips of the pogo pins 38a, 38b, . . . 38n that protrude upward from the probe holder.

This operation completes assembling of the test socket body 22.

Furthermore, if it is necessary to match the transmission impedance of the test socket, this may be done at the manufacturing stage by selecting the dielectric material of the probe retainer since the dielectric constant of this material may significantly influence the transmission impedance of the test socket. This feature is used for matching the transmission impedance of the socket with those on the input and output sides of the socket. The same can be achieved by selecting the thickness and diameter of the holes, parameters of the metal shields and insulating inserts.

Although the invention has been described in detail with reference to a specific embodiment, the method of the invention is not limited to the illustrated embodiment, and various changes and modifications are possible without deviation from the scope of the attached claims. For example, the sequence of the socket assembling may be different from the described above. Majority of manufacturing and assembling operations may be automated. For example, the holes may be preformed in the standard laminates of large and then the pretreated laminate may be cut into pieces of required dimensions. The upper and lower probe retainers may be both identical and coated from both side, or the upper one double-sided while the lower one is single sided. Hole filling with the inserts can be automated and multipositioned.

1. A method of manufacturing a test socket body used in a test socket for testing an object with a plurality of contact leads of the object with a measurement instrument, the method comprising the steps of:
providing a first commercially available laminate that comprises a dielectric sheet coated with a metal layer at least on one side;
providing a second commercially available laminate that comprises a dielectric sheet coated with a metal layer at least on one side and having second holes in the same positions and the first holes, the first holes and the second holes having inner diameters and inner surfaces;
providing a plurality of pogo pins for insertion into the first holes and the second holes, the pogo pins having outer diameters and outer surfaces;
providing a probe holder made of an electrically conductive material and having third holes for pogo pins which are formed in the same positions as the first and second holes, the third holes having an inner diameter and inner surfaces;
inserting the pogo pins into the third holes, and assembling the test socket body by sandwiching the probe holder with the pogo pins between the a first commercially available laminate and the second commercially available laminate so that the pogo pins are fit into the first and second holes.

2. The method of claim 1, further comprising the step of dividing the pogo pins into signal pogo pins, power pogo pins, and grounding pogo pins, and providing the third holes for grounding pogo pins with the inner diameter that provides electrical contact between the outer surfaces of the grounding pogo pins and the inner surfaces of the third holes, while the inner diameter of the third holes for control and power pogo pins are larger than the outer diameters of the control and power pogo pins for exclusion of the electrical contact between the inner surfaces of the third holes and the outer surfaces of the control and power pogo pins.

3. The method of claim 2, further providing the steps of:
coating at least the inner surfaces of each first hole with a metal layer thus obtaining first metal-coated holes;
filling the first metal-coated holes with a dielectric material thus forming dielectric fillings;
forming fourth holes in the dielectric fillings leaving at least partially the dielectric material between the metal layer and the second holes, thus producing a finished first probe retainer;
providing a second finished probe retainer which is similar to the first finished probe retainer and which is produced by repeating the manufacturing steps of the first finished probe retainer.

4. The method of claim 3, further providing a conductive substrate that has a plurality of contact pads the number of which corresponds to the number of the contact leads of the test object and which are intended for connecting the contact leads of the object to the measurement instrument.

5. The method of claim 3, further providing a pogo pin securing openings in the dielectric material of the first and second probe retainer left after forming the fourth holes, the positions of the pogo pin securing openings corresponding to the positions of the contact leads of the test object and said pogo pin securing openings being formed simultaneously with the step of forming the fourth holes in the dielectric fillings.

6. The method of claim 4, further providing a pogo pin securing openings in the dielectric material of the first and second probe retainer left after forming the fourth holes, the positions of the pogo pin securing openings corresponding to the positions of the contact leads of the test object and said pogo pin securing openings being formed simultaneously with the step of forming the fourth holes in the dielectric fillings.

7. The method of manufacturing a test socket body used in a test socket for testing an object with a plurality of contact leads, the method comprising the steps of:
providing a first laminate that comprises a dielectric sheet coated with a metal layer at least on one side;
forming in the metal-coated laminate a plurality of first through holes having inner surfaces and located in positions that correspond to positions of the contact leads of the test object;
coating at least the inner surfaces of each first through hole with a metal layer thus obtaining first metal-coated through holes;
filling the first metal-coated through holes with a dielectric material thus forming dielectric fillings;
forming second through holes in the dielectric fillings leaving at least partially the dielectric material between the metal layer and the second through holes, thus producing a finished first probe retainer;
providing a second finished probe retainer which is similar to the first finished probe retainer and which is produced by repeating the manufacturing steps of the first finished probe retainer;
providing a metallic probe holder comprising a metal plate having a plurality of third through holes the positions of which correspond to positions of the through holes in the first finished probe retainer and the second finished probe retainer;
providing a conductive substrate having a plurality of contact pads the number of which corresponds to the number of the contact leads of the test object and that are intended for connection to devices for measuring parameters of the test object;
providing a plurality of pogo pins that can be inserted into the second through holes of the first and second finished probe retainers;
providing a pogo pin securing openings in the dielectric material of the first and second probe retainer left after forming the second through holes, the positions of the pogo pin securing openings corresponding to the positions of the contact leads of the test object and said pogo pin securing openings being formed simultaneously with the step of forming second through holes in the dielectric fillings, the pogo pins being of a first type pogo pins and a second type pogo pins, wherein the pogo pins of the first type have an electrical contact with the third through holes via a press fit or sliding fit with the third through holes when inserted therein and the pogo pins of the second type do not have a physical and electrical contact with the third through holes when inserted therein; and
assembling the probe holder by inserting the pogo pins of the first type into the third through holes of the probe holder to contact with the support surface thus protruding the ends of the pogo pins of the first type from the probe holder, inserting the protruding ends of the pogo pins of the first type into securing openings of the second probe retainer, inserting the pogo pins of the second type into the third through openings of the probe holder and further to the pogo pin securing openings of the lower probe retainer, and fitting the pogo pin securing openings of the upper probe retainer on the ends of the pogo pins of the first and second type on the side opposite to the lower probe retainer thus completing assembling of the test socket body.

8. The method of claim 7, wherein the first laminate that comprises a commercially available laminate comprising a dielectric material coated at least on one side with a metal coating.

9. The method of claim 7, wherein the step of coating at least the inner surfaces of each first through hole with a metal layer is carried out by a method selected from the group consisting of electroplating, electroless deposition, and deposition in vacuum.

10. The method of claim 8, wherein the step of coating at least the inner surfaces of each first through hole with a metal layer is carried out by a method selected from the group consisting of electroplating, electroless deposition, and deposition in vacuum.

11. The method of claim 9, wherein the dielectric fillings are made from a dielectric material having a predetermined composition and thickness, and wherein the predetermined thickness and/or composition of the dielectric material of the dielectric fillings is used to obtain desired impedance and/or crosstalk-limiting characteristics.

12. The method of claim 10, wherein the dielectric fillings are made from a dielectric material having a predetermined composition and thickness, and wherein the predetermined thickness and/or composition of the dielectric material of the dielectric fillings is used to obtain desired impedance and/or crosstalk-limiting characteristics.
